(19) United States
(12) Patent Application Publication
(10) Pub. No.: US 2026/0090472 A1
(43) Pub. Date: Mar. 26, 2026

(54) METHOD OF MANUFACTURING A SEMICONDUCTOR PACKAGE

(71) Applicant: SK hynix Inc., Icheon-si Gyeonggi-do (KR)

(72) Inventor: Sang Hyeok JO, Icheon-si Gyeonggi-do (KR)

(73) Assignee: SK hynix Inc., Icheon-si Gyeonggi-do (KR)

(21) Appl. No.: 19/085,855

(22) Filed: Mar. 20, 2025

(30) Foreign Application Priority Data
Sep. 26, 2024 (KR) 10-2024-0130881

(51) Int. Cl. H01L 25/065; H01L 21/56; H01L 23/00; H10B 80/00

(52) U.S. Cl. CPC H10W 90/00; H10B 80/00; H10W 72/0198; H10W 72/327; H10W 72/865; H10W 72/884; H10W 72/9445; H10W 74/016; H10W 74/10; H10W 90/24; H10W 90/732; H10W 90/734; H10W 90/754

(57) ABSTRACT

A method of manufacturing a semiconductor package includes mounting a first semiconductor die over a package substrate, forming a first connector to electrically connect the first semiconductor die to the package substrate, offset-stacking a second semiconductor die over the first semiconductor die in a first direction, offset-stacking a third semiconductor die on the second semiconductor die in a second direction, offset-stacking a fourth semiconductor die on the third semiconductor die in the second direction, forming a second connector to electrically connect the second semiconductor die to the package substrate, forming a third connector to electrically connect the third semiconductor die to the package substrate, and forming a fourth connector to electrically connect the fourth semiconductor die to the package substrate.

### CROSS-REFERENCE TO RELATED APPLICATION

The present application claims priority under 35 U.S.C. § 119(a) to Korean Patent Application No. 10-2024-0130881, filed on Sep. 26, 2024, in the Korean Intellectual Property Office, which application is incorporated herein by reference in its entirety.

### BACKGROUND

### 1. Technical Field The present disclosure generally relates to a semiconductor package and a method of manufacturing a semiconductor package.

### 2. Related Art

A semiconductor package having a plurality of offset-stacked semiconductor dies has been proposed.

### SUMMARY

In accordance with an embodiment of the present disclosure, a semiconductor package may include a package substrate; a first semiconductor die mounted over the package substrate; a second semiconductor die that is offset-stacked over the first semiconductor die in a first direction; a third semiconductor die that is offset-stacked over the second semiconductor die in a second direction; and a fourth semiconductor die that is offset-stacked over the third semiconductor die in the second direction. The first direction is opposite to the second direction. The first semiconductor die may include a first semiconductor chip and a first adhesive layer. The second semiconductor die may include a second semiconductor chip and a second adhesive layer. The third semiconductor die may include a third semiconductor chip and a third adhesive layer. The fourth semiconductor die may include a fourth semiconductor chip and a fourth adhesive layer. The first adhesive layer has a first thickness. Each of the second to fourth adhesive layers has a second thickness. The first thickness is thicker than the second thickness.

In accordance with an embodiment of the present disclosure, a semiconductor package may include a package substrate; a first semiconductor chip mounted over the package substrate; a second semiconductor chip offset-stacked over the first semiconductor chip in a first direction; a third semiconductor chip offset-stacked over the second semiconductor chip in a second direction; and a fourth semiconductor chip offset-stacked over the third semiconductor chip in the second direction. The package substrate may include a first side, a second side, and first to fourth substrate pads. The first side is opposite to the second side. The first substrate pad and the fourth substrate pad are disposed closer to the second side than the first side. The second substrate pad and the third substrate pad are disposed closer to the first side than the second side. The first semiconductor chip may include a first chip pad disposed closer to the second side than the first side. The second semiconductor chip may include a second chip pad disposed closer to the first side than the second side. The third semiconductor chip may include a third chip pad disposed closer to the first side than the second side. The fourth semiconductor chip may include a fourth chip pad disposed closer to the second side than the first side.

In accordance with an embodiment of the present disclosure, a method of manufacturing a semiconductor package may include mounting a first semiconductor die over a package substrate, forming a first connector to electrically connect the first semiconductor die to the package substrate, offset-stacking a second semiconductor die over the first semiconductor die in a first direction, offset-stacking a third semiconductor die on the second semiconductor die in a second direction, offset-stacking a fourth semiconductor die on the third semiconductor die in the second direction, forming a second connector to electrically connect the second semiconductor die to the package substrate, forming a third connector to electrically connect the third semiconductor die to the package substrate, and forming a fourth connector to electrically connect the fourth semiconductor die to the package substrate.

In accordance with an embodiment of the present disclosure, method of manufacturing a semiconductor package may include forming a first adhesive film having a first thickness over a backside surface of a first wafer, forming a second adhesive film having a second thickness over a backside surface of a second wafer, dicing the first wafer and the first adhesive film to form a first semiconductor die having a first semiconductor chip and a first adhesive layer, dicing the second wafer and the second adhesive film to form second to fourth semiconductor dies having second to fourth semiconductor chips and second to fourth adhesive layers, respectively, mounting the first semiconductor die on a package substrate, and stacking the second to fourth semiconductor dies over the first semiconductor die. The first adhesive film has a first thickness. The second adhesive film has a second thickness. The first thickness is thicker than the second thickness.

### BRIEF DESCRIPTION OF THE DRAWINGS

FIG. 1A is a side view schematically illustrating a semiconductor package according to an embodiment of the present disclosure, FIG. 1B is an enlarged view of an area ‘A’ of FIG. 1A, and FIG. 1C is an enlarged view of an area ‘B’of FIG. 1A.

FIG. 2 is a side view schematically illustrating a semiconductor package according to an embodiment of the present disclosure.

FIGS. 3A to 3F are views illustrating a method of manufacturing a semiconductor package according to an embodiment of the present disclosure.

FIGS. 4A to 4E are views illustrating a method of manufacturing a semiconductor package according to an embodiment of the present disclosure.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. Embodiments of the present disclosure are directed to a semiconductor die stack structure including a plurality of semiconductor dies that are stacked therein, and a method of manufacturing the semiconductor die stack structure. Embodiments of the present disclosure are directed to a base-bottom die stack structure in which a base die and a bottom die are bonded, and a method of manufacturing the base-bottom die stack structure. Embodiments of the present disclosure are directed to a method of stacking middle dies and a top die over a base-bottom die stack structure. Embodiments of the present disclosure are directed to a semiconductor stack structure including middle dies and a top die that are stacked over a base-bottom die stack structure.

Throughout the specification, an expression “close to the first side of the package substrate” can be interpreted as a meaning of “closer to the first side of the package substrate than the second side of the package substrate”, and an expression “close to the second side of the package substrate” can be interpreted as a meaning of “closer to the second side of the package substrate than the first side of the package substrate”.

An embodiment of the present disclosure provides a semiconductor package having a plurality of offset-stacked semiconductor dies.

An embodiment of the present disclosure provides a method of manufacturing a semiconductor package having a plurality of offset-stacked semiconductor dies.

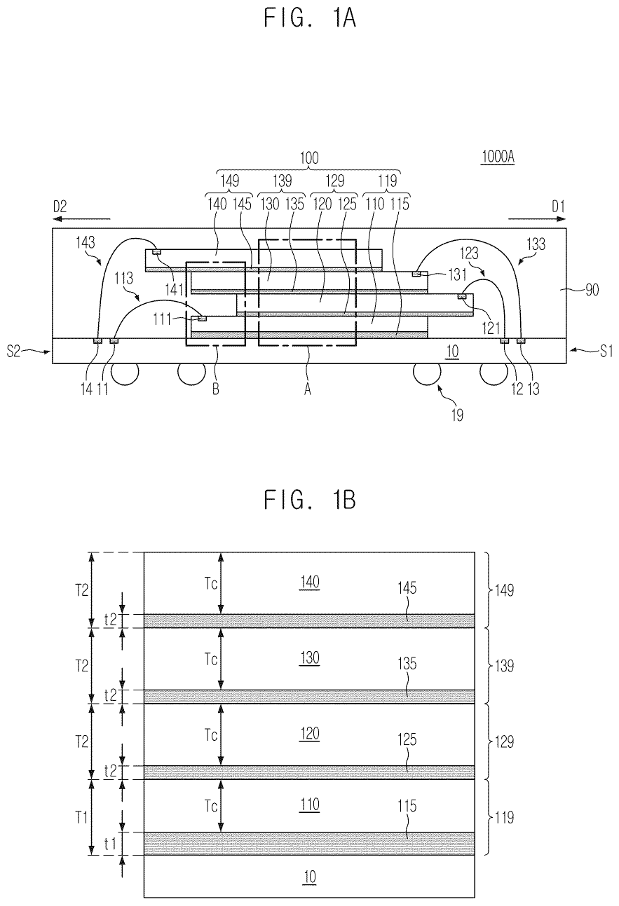

FIG. 1A is a side view schematically illustrating a semiconductor package 1000A according to an embodiment of the present disclosure, FIG. 1B is an enlarged view of an area ‘A’ of FIG. 1A, and FIG. 1C is an enlarged view of an area ‘B’of FIG. 1A.

Referring to FIGS. 1A to 1C, the semiconductor package 1000A according to an embodiment of the present disclosure may include a semiconductor chip stack 100 mounted on a package substrate 10. The semiconductor package 1000A may further include connectors 113, 123, 133, and 143 electrically connecting the package substrate 10 to the semiconductor chip stack 100. The connectors 113, 123, 133, and 143 may include a first connector 113, a second connector 123, a third connector 133, and a fourth connector 143. Each of the first to fourth connectors 113, 123, 133, and 143 may include a bonding wire. The semiconductor package 1000A may further include a molding member 90 that surrounds and covers the semiconductor chip stack 100 and the first to fourth connectors 113, 123, 133, and 143.

The package substrate 10 may further include substrate pads 11, 12, 13, and 14 and external connectors 19. The substrate pads 11, 12, 13, and 14 may be disposed on an upper surface of the package substrate 10, and the external connectors 19 may be disposed on a lower surface of the package substrate 10. The substrate pads 11, 12, 13, and 14 and the external connectors 19 may be selectively and electrically connected to each other. The substrate pads 11, 12, 13, and 14 may include a first substrate pad 11, a second substrate pad 12, a third substrate pad 13, and a fourth substrate pad 14. The first substrate pad 11 and the fourth substrate pad 14 may be disposed close to a second side S2 of the package substrate 10, and the second substrate pad 12 and the third substrate pad 13 may be disposed close to a first side S1 of the package substrate 10. The first to fourth substrate pads 11, 12, 13, and 14 may include a metal such as copper. The external connectors 19 may include solder balls. The package substrate 10 may include a printed circuit board (PCB). In some embodiments, the package substrate 10 may include one of a redistribution layer or a silicon-based interposer.

A direction from the second side S2 to the first side S1 of the package substrate 10 is defined as a first direction D1, and a direction from the first side S1 to the second side S2 of the package substrate 10 is defined as a second direction D2. The first and second directions D1 and D2 may be opposite to each other. The first side S1 and the second side S2 may be opposite to each other.

The semiconductor chip stack 100 may include a plurality of stacked semiconductor dies 119, 129, 139, and 149. For example, the semiconductor chip stack 100 may include a first semiconductor die 119, a second semiconductor die 129 stacked on the first semiconductor die 119, a third semiconductor die 139 stacked on the second semiconductor die 129, and a fourth semiconductor die 149 stacked on the third semiconductor die 139. The first semiconductor die 119 may include a first semiconductor chip 110 and a first adhesive layer 115 on an lower surface of the first semiconductor chip 110, the second semiconductor die 129 may include a second semiconductor chip 120 and a second adhesive layer 125 on an lower surface of the second semiconductor chip 120, the third semiconductor die 139 may include a third semiconductor chip 130 and a third adhesive layer 135 on an lower surface of the third semiconductor chip 130, and the fourth semiconductor die 149 may include a fourth semiconductor chip 140 and a fourth adhesive layer 145 on an lower surface of the fourth semiconductor chip 140. The first to fourth semiconductor chips 110, 120, 130, and 140 may be the same memory chips. The first to fourth adhesive layers 115, 125, 135, and 145 may include a Wafer Backside Lamination (WBL) tape. In an embodiment, the first to fourth adhesive layers 115, 125, 135, and 145 may include a die attach film (DAF).

The first semiconductor die 119 may be directly mounted on the package substrate 10. The first semiconductor chip 110 may be directly adhered and stacked on the package substrate 10 by using the first adhesive layer 115. A horizontal length of the first adhesive layer 115 may be substantially equal to a horizontal length of the first semiconductor chip 110.

The first semiconductor chip 110 of the first semiconductor die 119 may include a first chip pad 111. The first chip pad 111 may be disposed on an exposed upper surface of the first semiconductor chip 110 close to the second side S2 of the package substrate 10. The first chip pad 111 may be electrically connected to the first substrate pad 11 of the package substrate 10 through the first connector 113. The first connector 113 may be disposed close to the second side S2 of the package substrate 10.

The second semiconductor die 129 may be offset-stacked on the first semiconductor die 119 in the first direction D1. The second semiconductor chip 120 may be directly adhered and stacked on the first semiconductor chip 110 by using the second adhesive layer 125. A horizontal length of the second adhesive layer 125 may be substantially equal to a horizontal length of the second semiconductor chip 120. The second semiconductor die 129 may be offset in the first direction D1 to overhang from the first semiconductor die 119 to be close to the first side S1 of the package substrate 10. One side end of the second semiconductor die 129 may laterally protrude from one side end of the first semiconductor die 119 in the first direction D1. One portion of the upper surface of the first semiconductor chip 110 close to the second side S2 of the package substrate 10 may be exposed so that the first chip pad 111 of the first semiconductor chip 110 is exposed. The other portion of the upper surface of the first semiconductor chip 110 close to the first side S1 of the package substrate 10 might not be exposed by the second semiconductor die 129.

The second semiconductor chip 120 of the second semiconductor die 129 may include a second chip pad 121. The second chip pad 121 may be disposed on an exposed upper surface of the second semiconductor chip 120 close to the first side S1 of the package substrate 10. The second chip pad 121 may be electrically connected to the second substrate pad 12 of the package substrate 10 through the second connector 123. The second connector 123 may be disposed close to the first side S1 of the package substrate 10.

The third semiconductor die 139 may be offset-stacked on the second semiconductor die 129 in the second direction D2. The third semiconductor chip 130 may be directly adhered and stacked on the second semiconductor chip 120 by using the third adhesive layer 135. A horizontal length of the third adhesive layer 135 may be substantially equal to a horizontal length of the third semiconductor chip 130. The third semiconductor die 139 may be offset in the second direction D2 to overhang from the second semiconductor die 129 to be close to the second side S2 of the package substrate 10. One side end of the third semiconductor die 139 may laterally protrude from one side end of the second semiconductor die 120 in the second direction D2. One portion of the upper surface of the second semiconductor chip 120 close to the first side S1 of the package substrate 10 may be exposed so that the second chip pad 121 of the second semiconductor chip 120 is exposed. The other portion of the upper surface of the second semiconductor chip 120 close to the second side S2 of the package substrate 10 might not be exposed by the third semiconductor die 139. Accordingly, a space Sp1 may be formed between the first semiconductor die 119 and the third semiconductor die 139 by being shifting or offsetting the second semiconductor die 129 in the first direction D1.

The third semiconductor chip 130 of the third semiconductor die 139 may include a third chip pad 131. The third chip pad 131 may be disposed on an exposed upper surface of the third semiconductor chip 130 to be close to the first side S1 of the package substrate 10. The third chip pad 131 may be electrically connected to the third substrate pad 13 of the package substrate 10 through the third connector 133. The third connector 133 may be disposed close to the first side S1 of the package substrate 10.

The fourth semiconductor die 149 may be offset-stacked on the third semiconductor die 139 in the second direction D2. The fourth semiconductor chip 140 may be directly adhered and stacked on the third semiconductor chip 130 by using the fourth adhesive layer 145. A horizontal length of the fourth adhesive layer 145 may be substantially equal to a horizontal length of the fourth semiconductor chip 140. The fourth semiconductor die 149 may be offset in the second direction D2 to overhang from the third semiconductor die 139 to be close to the second side S2 of the package substrate 10. One side end of the fourth semiconductor die 149 may laterally protrude from a side end of the first semiconductor die 119 and a side end of the third semiconductor die 139 in the second direction D2. One portion of the upper surface of the third semiconductor chip 130 close to the first side S1 of the package substrate 10 may be exposed so that the third chip pad 131 of the third semiconductor chip 130 is exposed. The other portion of the upper surface of the third semiconductor chip 130 close to the second side S2 of the package substrate 10 might not be exposed by the fourth semiconductor die 149.

The fourth semiconductor chip 140 of the fourth semiconductor die 149 may include a fourth chip pad 141. The fourth chip pad 141 may be disposed on an exposed upper surface of the fourth semiconductor chip 140 to be close to the second side S2 of the package substrate 10. The fourth chip pad 141 may be electrically connected to the fourth substrate pad 14 of the package substrate 10 through the fourth connector 143. The fourth connector 143 may be disposed close to the second side s2 of the package substrate 10.

The second semiconductor die 129, the third semiconductor die 139, and the fourth semiconductor die 149 may be offset-stacked on the first semiconductor die 119 in a three-layered staircase form (i.e., a cascade form) that rise in series in the second direction D2 from the first side S1 to the second side S2 of the package substrate 10. In an embodiment, the first semiconductor die 119 and the third semiconductor die 139 may be vertically and accurately aligned and overlapped with each other.

As mentioned above, the first chip pad 111 of the first semiconductor chip 110, the first connector 113, the fourth chip pad 141 of the fourth semiconductor chip 140, and the fourth connector 143 may be disposed close to the second side S2 of the package substrate 10 than the first side S1 of the package substrate 10, and the second chip pad 121 of the second semiconductor chip 120, the second connector 123, the third chip pad 131 of the third semiconductor chip 130, and the third connector 133 may be disposed closer to the first side S1 of the package substrate 10.

The semiconductor chip stack 100 may include semiconductor dies 119, 129, 139, and 149 stacked in a vertical zigzag stack structure. The second semiconductor die 129 may be stacked on the first semiconductor die 119 to be offset in the first direction D1. The third semiconductor die 139 may be stacked on the second semiconductor die 129 to be offset in the second direction D2, and the fourth semiconductor die 149 may be stacked on the third semiconductor die 139 to be offset in the second direction D2.

The first adhesive layer 115 may have a first thickness t1. The second adhesive layer 125, the third adhesive layer 135, and the fourth adhesive layer 145 may have a second thickness t2. That is, thicknesses of the second adhesive layer 125, the third adhesive layer 135, and the fourth adhesive layer 145 may be equal to each other. The first thickness t1 may be greater than the second thickness t2. In an embodiment, the second thickness t2 may be equal to or less than half of the first thickness t1. In an embodiment, the first thickness t1 may be greater than 10 micrometer (um), and the second thickness t2 may be equal to or less than 10 um. In an embodiment, a thickness may be a vertical thickness whereby the vertical direction used to measure the vertical thickness is in the stacking direction of, for example, the semiconductor chips (i.e., 110, 120, 130, and 140).

In an embodiment, the upper surface of the package substrate may be contaminated in a semiconductor package manufacturing process. For example, foreign substances may be separated from package manufacturing equipment or raw materials and may remain on the surface of the package substrate. Among them, in an embodiment, the foreign substances having a size between 5 μm and 10 μm affect surrounding structures in the semiconductor package. In an embodiment, when some foreign substances remain on the package substrate, adhesion between the semiconductor die and the package substrate may become weak and decline. In an embodiment, when the size of the foreign substances is greater than the thickness of the adhesive layer, stress may be applied to the semiconductor die while contacting both sides between the package substrate and the semiconductor die. As a result, in an embodiment, defects such as die cracks may occur. Therefore, in an embodiment, the adhesive layer should have a sufficient thickness to completely bury the foreign substances.

In an embodiment, the thickness of the adhesive layer in the semiconductor package have to be limited. The adhesive layer, in an embodiment, is required to attach the semiconductor die to another semiconductor die. In an embodiment, as the number of stacked semiconductor dies increases, the thickness of the semiconductor package due to the adhesive layer also increases. Therefore, in an embodiment, in order to stack many semiconductor dies within a limited space and thickness, the thickness of the adhesive layer have to be limited.

According to an embodiment, the first adhesive layer 115 has a thickness thicker than the size of foreign substances on the surface of the package substrate 10, but the second adhesive layer 125, the third adhesive layer 135, and the fourth adhesive layer 145 that are not in contact with the package substrate have a thickness thinner than the thickness of the first adhesive layer 115. Therefore, in an embodiment, the thickness of the semiconductor package 1000A can be minimized.

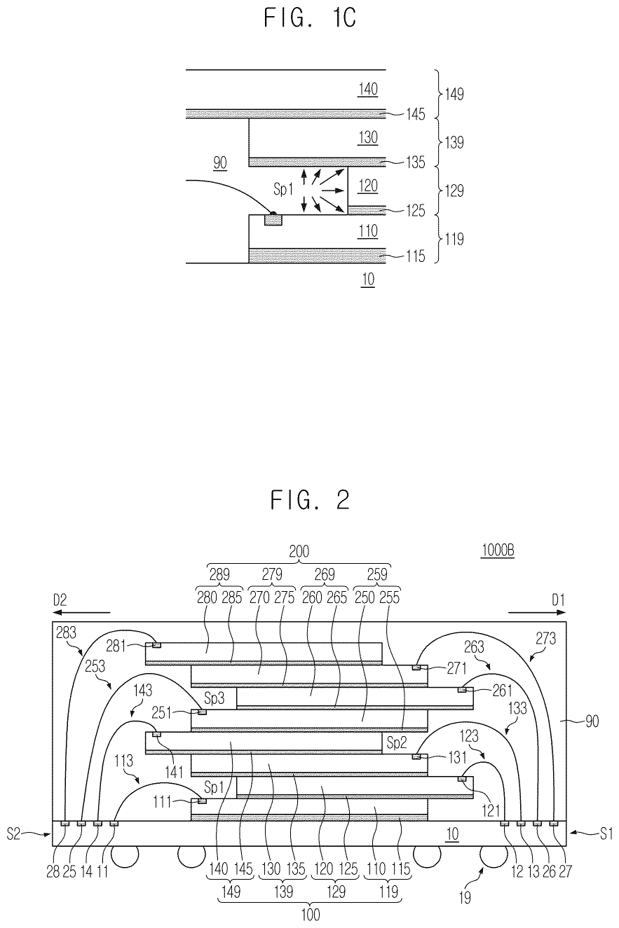

FIG. 2 is a side view schematically illustrating a semiconductor package 1000B according to an embodiment of the present disclosure. Referring to FIG. 2, the semiconductor package 1000B may include a semiconductor chip stack 100 stacked on the package substrate 10 and an additional semiconductor chip stack 200 stacked on the semiconductor chip stack 100. Descriptions of components overlapping with FIGS. 1A to 1C are omitted. The semiconductor package 1000B may further include additional connectors 253, 263, 273, and 283 electrically connecting the package substrate 10 to the additional semiconductor chip stack 200. The additional connectors 253, 263, 273, and 283 may include a fifth connector 253, a sixth connector 263, a seventh connector 273, and an eighth connector 283. Each of the additional connectors 253, 263, 273, and 283 may include a bonding wire.

The package substrate 10 may further include additional substrate pads 25, 26, 27, and 28. The additional substrate pads 25, 26, 27, and 28 may include a fifth substrate pad 25, a sixth substrate pad 26, a seventh substrate pad 27, and an eighth substrate pad 28. The fifth substrate pad 25 and the eighth substrate pad 28 may be disposed to be close to the second side S2 of the package substrate 10. The sixth substrate pad 26 and the seventh substrate pad 27 may be disposed to be close to the first side S1 of the package substrate 10.

The additional semiconductor chip stack 200 may include additional semiconductor dies 259, 269, 279, and 289. The additional semiconductor dies 259, 269, 279, and 289 may include additional semiconductor chips 250, 260, 270, and 280 and additional adhesive layers 255, 265, 275, and 285, respectively. The additional semiconductor chips 250, 260, 270, and 280 may include a fifth semiconductor chip 250, a sixth semiconductor chip 260, a seventh semiconductor chip 270, and an eighth semiconductor chip 280. The additional adhesive layers 255, 265, 275, and 285 may include a fifth adhesive layer 255, a sixth adhesive layer 265, a seventh adhesive layer 275, and an eighth adhesive layer 285.

The fifth semiconductor die 259 may be offset-stacked on the fourth semiconductor die 149 in the first direction D1. The fifth semiconductor chip 250 may be directly adhered and stacked on the fourth semiconductor chip 140 by using the fifth adhesive layer 255. A horizontal length of the fifth adhesive layer 255 may be substantially equal to a horizontal length of the fifth semiconductor chip 250. The fifth semiconductor die 259 may be offset in the first direction D1 to overhang from the fourth semiconductor die 149 to be close to the first side S1 of the package substrate 10. One side end of the fifth semiconductor die 250 may laterally protrude from a side end of the first semiconductor die 110 in the first direction D1. One portion of the upper surface of the fourth semiconductor chip 140 close to the second side S2 of the package substrate 10 may be exposed so that the fourth chip pad 141 of the fourth semiconductor chip 140 is exposed. The other portion of the upper surface of the fourth semiconductor chip 140 close to the first side S1 of the package substrate 10 might not be exposed by the fifth semiconductor die 259. Accordingly, a space Sp2 may be formed between the third semiconductor die 139 and the fifth semiconductor die 259 by shifting or offsetting the fourth semiconductor die 149 in the second direction D2.

The fifth semiconductor chip 250 of the third semiconductor die 259 may include a fifth chip pad 251. The fifth chip pad 251 may be disposed on an exposed upper surface of the fifth semiconductor chip 250 to be close to the second side S2 of the package substrate 10. The fifth chip pad 251 may be electrically connected to the fifth substrate pad 25 of the package substrate 10 through a fifth connector 253. The fifth connector 253 may be disposed close to the second side S2 of the package substrate 10.

The sixth semiconductor die 269 may be further offset-stacked on the fifth semiconductor die 259 in the first direction D1. The sixth semiconductor chip 260 may be directly adhered and stacked on the fifth semiconductor chip 250 by using the sixth adhesive layer 265. A horizontal length of the sixth adhesive layer 265 may be substantially equal to a horizontal length of the sixth semiconductor chip 260. The sixth semiconductor die 269 may be offset in the first direction D1 to overhang from the fifth semiconductor die 259 to be close to the first side S1 of the package substrate 10. One side end of the sixth semiconductor die 269 may laterally protrude from a side end of the fifth semiconductor die 259 in the first direction D1. One portion of the upper surface of the fifth semiconductor chip 250 close to the second side S2 of the package substrate 10 may be exposed so that the fifth chip pad 251 of the fifth semiconductor chip 250 is exposed. The other portion of the upper surface of the fifth semiconductor chip 250 close to the first side S1 of the package substrate 10 might not be exposed by the sixth semiconductor die 269.

The sixth semiconductor chip 260 of the sixth semiconductor die 269 may include a sixth chip pad 261. The sixth chip pad 261 may be disposed on an exposed upper surface of the sixth semiconductor chip 260 to be close to the first side S1 of the package substrate 10. The sixth chip pad 261 may be electrically connected to the sixth substrate pad 26 of the package substrate 10 through a sixth connector 263. The sixth connector 263 may be disposed close to the first side S1 of the package substrate 10.

The seventh semiconductor die 279 may be offset-stacked on the sixth semiconductor die 269 in the second direction D2. The seventh semiconductor chip 270 may be directly adhered and stacked on the sixth semiconductor chip 260 by using a seventh adhesive layer 275. A horizontal length of the seventh adhesive layer 275 may be substantially equal to a horizontal length of the seventh semiconductor chip 270. The seventh semiconductor die 279 may be offset in the second direction D2 to overhang from the sixth semiconductor die 269 to be close to the second side S2 of the package substrate 10. One side end of the seventh semiconductor die 279 may laterally protrude from a side end of the sixth semiconductor die 269 in the second direction D2. One portion of the upper surface of the sixth semiconductor chip 260 close to the first side S1 of the package substrate 10 may be exposed so that the sixth chip pad 261 of the sixth semiconductor chip 260 is exposed. The other portion of the upper surface of the sixth semiconductor chip 260 close to the second side S2 of the package substrate 10 might not be exposed by the seventh semiconductor die 279. Accordingly, a space Sp3 may be formed between the fifth semiconductor die 259 and the seventh semiconductor die 279 by shifting or offsetting the sixth semiconductor die 269 in the first direction D1.

The seventh semiconductor chip 270 of the seventh semiconductor die 279 may include a seventh chip pad 271. The seventh chip pad 271 may be disposed on an exposed upper surface of the seventh semiconductor chip 270 to be close to the first side S1 of the package substrate 10. The seventh chip pad 271 may be electrically connected to the seventh substrate pad 27 of the package substrate 10 through a seventh connector 273. The seventh connector 273 may be disposed close to the first side S1 of the package substrate 10.

The eighth semiconductor die 289 may be further offset-stacked on the seventh semiconductor die 279 in the second direction D2. The eighth semiconductor chip 280 may be directly adhered and stacked on the seventh semiconductor chip 270 by using the eighth adhesive layer 285. A horizontal length of the eighth adhesive layer 285 may be substantially equal to a horizontal length of the eighth semiconductor chip 280. The eighth semiconductor die 289 may be offset in the second direction D2 to overhang from the seventh semiconductor die 279 to be close to the second side S2 of the package substrate 10. One side end of the eighth semiconductor die 280 may laterally protrude from side ends of the first, third, fifth, and seventh semiconductor dies 119, 139, 259, and 279 in the second direction D2. One portion of the upper surface of the seventh semiconductor chip 270 close to the first side S1 of the package substrate 10 may be exposed so that the seventh chip pad 271 of the seventh semiconductor chip 270 is exposed. The other portion of the upper surface of the seventh semiconductor chip 270 close to the second side S2 of the package substrate 10 might not be exposed by the eighth semiconductor die 289.

The eighth semiconductor chip 280 of the eighth semiconductor die 289 may include an eighth chip pad 281. The eighth chip pad 281 may be disposed on an exposed upper surface of the eighth semiconductor chip 280 to be close to the second side S2 of the package substrate 10. The eighth chip pad 281 may be electrically connected to the eighth substrate pad 28 of the package substrate 10 through an eighth connector 283. The eighth connector 283 may be disposed close to the second side S2 of the package substrate 10.

The fourth semiconductor die 149, the fifth semiconductor die 259, and the sixth semiconductor die 269 may be stacked on the third semiconductor die 139 in a three-layered staircase form (i.e., a cascade form) that rises in a series from the second side S2 of the package substrate 10 toward the first side S1. The sixth semiconductor die 269, the seventh semiconductor die 279, and the eighth semiconductor die 289 may be stacked on the fifth semiconductor die 259 in a three-layered staircase form (i.e., a cascade form) that rise in series in the second direction D2 from the first side S1 to the second side S2 of the package substrate 10. In an embodiment, the first semiconductor die 119, the third semiconductor die 139, the fifth semiconductor die 259, and the seventh semiconductor die 279 may be vertically and accurately aligned and overlapped with each other. In an embodiment, the second semiconductor die 129 and the sixth semiconductor die 269 may be vertically and accurately aligned and overlapped with each other. In an embodiment, the fourth semiconductor die 149 and the eighth semiconductor die 289 may be vertically and accurately aligned and overlapped with each other.

The first chip pad 111, the first connector 113, the first substrate pad 11, the fourth chip pad 141, the fourth connector 143, the fourth substrate pad 14, the fifth chip pad 251, the fifth connector 253, the fifth substrate pad 25, the eighth chip pad 281, the eighth connector 283, and the eighth substrate pad 28 may be disposed close to the second side S2 of the package substrate 10. The second chip pad 121, the second connector 123, the second substrate pad 12, the third chip pad 131, the third connector 133, the third substrate pad 13, the sixth chip pad 261, the sixth connector 263, the sixth substrate pad 26, the seventh chip pad 271, the seventh connector 273, and the seventh substrate pad 27 may be disposed close to the first side S1 of the package substrate 10.

The additional semiconductor chip stack 200 may include the semiconductor dies 259, 269, 279, and 289 stacked in a vertical zigzag stack structure. The fifth semiconductor die 259 may be stacked on the fourth semiconductor die 149 to be offset in the first direction D1. The sixth semiconductor die 269 may be stacked on the fifth semiconductor die 259 to be offset in the first direction 1D. The seventh semiconductor die 279 may be stacked on the sixth semiconductor die 269 to be offset in the second direction D2. The eighth semiconductor die 289 may be stacked on the seventh semiconductor die 279 to be offset in the second direction D2. In the vertical zigzag stack structure, the fifth semiconductor die 259 and the eighth semiconductor die 289 may be offset-stacked such that the fifth chip pad 251 and the eighth chip pad 281 are disposed close to the second side S2 of the package substrate 10, and the sixth semiconductor die 269 and the seventh semiconductor die 279 may be offset-stacked such that the sixth chip pad 261 and the seventh chip pad 271 are disposed close to the first side S1 of the package substrate 10.

In an embodiment, the fifth to eighth adhesive layers 255, 265, 275, and 285 may include the WBL. In an embodiment, the fifth adhesive layer 255, the sixth adhesive layer 265, the seventh adhesive layer 275, and the eighth adhesive layer 285 may have the second thickness t2. In an embodiment, the fifth to eighth adhesive layers 255, 265, 275, and 285 may include the DAF.

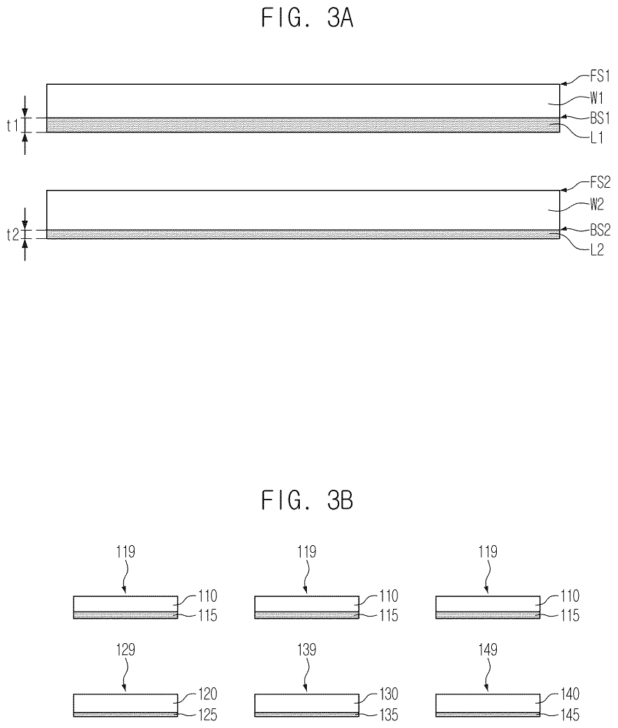

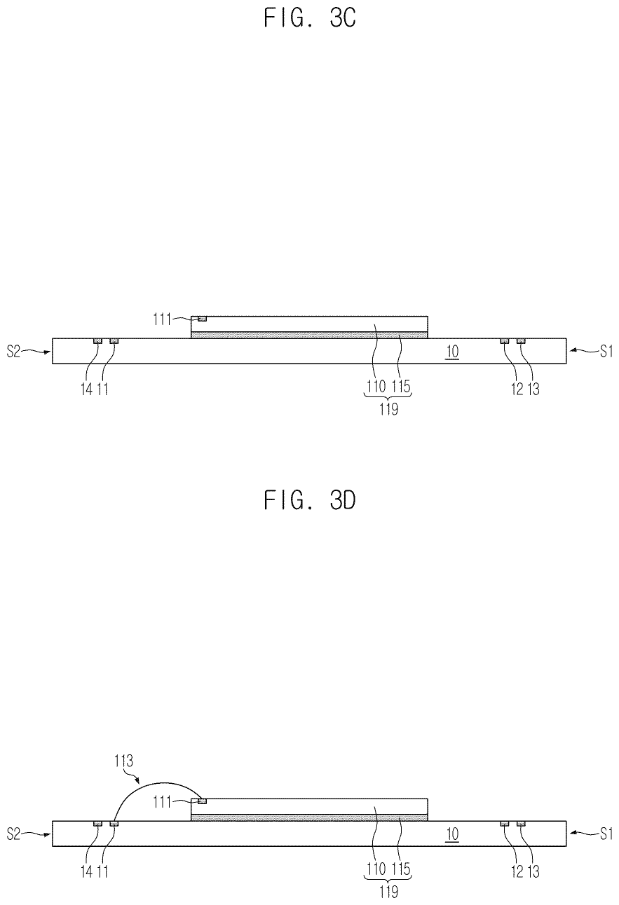

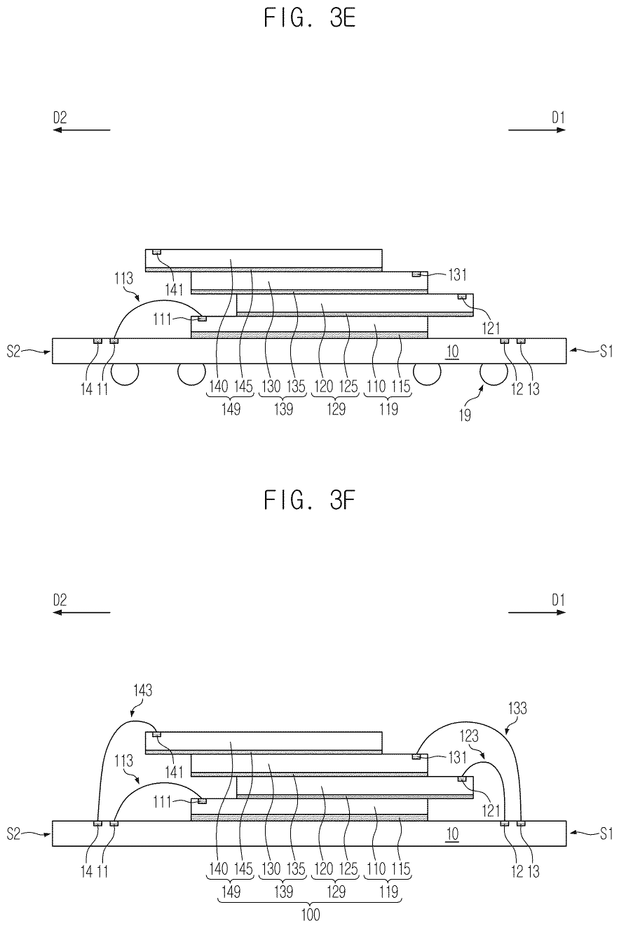

FIGS. 3A to 3F are views illustrating a method of manufacturing a semiconductor package according to an embodiment of the present disclosure.

Referring to FIG. 3A, the method may include preparing a first wafer W1 and a second wafer W2, forming a first adhesive film L1 on a backside surface BS1, i.e., an inactive surface, of the first wafer W1, and forming a second adhesive film L2 on a backside surface BS2, i.e., an inactive surface, of the second wafer W2. The first and second wafers W1 and W2 may include transistors, electrical interconnections, and connection pads formed on frontside surfaces FS1 and FS2, respectively. The first and second wafers W1 and W2 may be thinned wafers by performing a backside grinding process. The first and second adhesive films L1 and L2 may include the WBL. In an embodiment, the first and second adhesive films L1 and L2 may include the DAF. The first adhesive film L1 may have a first thickness t1, and the second adhesive film L2 may have a second thickness t2. The first thickness t1 may be thicker than the second thickness t2. For example, the first thickness t1 may be equal to or greater than 15 μm, and more specifically, about equal to or greater than 20 μm. The second thickness t2 may be equal to or less than 15 μm, and more specifically, about equal to or less than 10 μm.

Referring to FIG. 3B, the method may further include performing a dicing process to separate the first wafer W1 and the first adhesive film L1 to make a plurality of first semiconductor dies 119, and to separate the second wafer W2 and the second adhesive films L2 to make a plurality of second to fourth semiconductor dies 129, 139, and 149. The dicing process may include a stealth dicing process. In an embodiment, the dicing process may include a sawing process. The first semiconductor die 119 may include a first semiconductor chip 110 and a first adhesive layer 115 on a lower surface (i.e., a backside surface) of the first semiconductor chip 110. The second semiconductor die 129 may include a second semiconductor chip 120 and a second adhesive layer 125 on a lower surface (i.e., a backside surface) of the second semiconductor chip 120. The third semiconductor die 139 may include a third semiconductor chip 130 and a third adhesive layer 135 on a lower surface (i.e., a backside surface) of the third semiconductor chip 130. The fourth semiconductor die 149 may include a fourth semiconductor chip 140 and a fourth adhesive layer 145 on a lower surface (i.e., a backside surface) of the fourth semiconductor chip 140.

Referring to FIG. 3C, the method may further include performing a first chip stack process to mount the first semiconductor die 119 on a package substrate 10. The first semiconductor chip 110 may be adhered and mounted on the package substrate 10 using the first adhesive layer 115. The package substrate 10 may have a first side S1 and a second side S2. The first side S1 and the second side S2 may be opposite to each other. The package substrate 10 may include a first substrate pad 11, a second substrate pad 12, a third substrate pad 13, and a fourth substrate pad 14 disposed on an upper surface of the package substrate 10. The first substrate pad 11 and the fourth substrate pad 14 may be disposed close to the second side S2 of the package substrate 10, and the second substrate pad 12 and the third substrate pad 13 may be disposed close to the first side S1 of the package substrate 10. The first semiconductor chip 110 may include a first chip pad 111 disposed on an upper surface of the first semiconductor chip 110 that is close to the second side S2 of the package substrate 10.

Referring to FIG. 3D, the method may further include performing a first connecting process to form a first connector 113 electrically connecting the first chip pad 111 of the first semiconductor chip 110 to the first substrate pad 11 of the package substrate 10 using a first connector 113. The first connector 113 may include a bonding wire. The first connector 113 may be disposed close to the second side S2 of the package substrate 10. The first connecting process may include a first wire bonding process.

Referring to FIG. 3E, the method may further include continuously stacking a second semiconductor die 129, a third semiconductor die 139, and a fourth semiconductor die 149 on the first semiconductor die 119 by performing a second chip stack process. The second semiconductor die 129 may be offset-stacked in the first direction D1 from the first semiconductor chip 110 toward the first side S1 of the package substrate 10 so that a portion of the upper surface on which the first chip pad 111 disposed is exposed. The second semiconductor chip 120 may include a second chip pad 121 disposed on an upper surface of the second semiconductor chip 120 close to the first side S1 of the package substrate 10. The third semiconductor die 139 may be offset-stacked in the second direction D2 from the second semiconductor chip 120 toward the second side S2 of the package substrate 10 so that a portion of the upper surface on which the second chip pad 121 disposed is exposed. The third semiconductor chip 130 may include a third chip pad 131 disposed on an upper surface of the third semiconductor chip 130 close to the first side S1 of the package substrate 10. The fourth semiconductor die 149 may be offset-stacked from the third semiconductor chip 130 in the second direction D2 so that a portion of the upper surface on which the third chip pad 131 disposed is exposed. The fourth semiconductor chip 140 may include a fourth chip pad 141 disposed on an upper surface thereof close to the second side S2 of the package substrate 10. The first direction D1 and the second direction S2 may be opposite to each other.

Referring to FIG. 3F, the method may further include performing a second connecting process to form a second connector 123 electrically connecting the second chip pad 121 of the second semiconductor chip 120 to the second substrate pad 12 of the package substrate 10, a third connector 133 electrically connecting the third chip pad 131 of the third semiconductor chip 130 to the third substrate pad 13 of the package substrate 10, and a fourth connector 143 electrically connecting the fourth chip pad 141 of the fourth semiconductor chip 140 to the fourth substrate pad 14 of the package substrate 10. Each of the second connector 123, the third connector 133, and the fourth connector 143 may include a bonding wire. The second connecting process may include a second wire bonding process. The second connecting process may include continuously forming the second connector 123, the third connector 133, and the fourth connector 143. The second connector 123 and the third connector 133 may be formed close to the first side S1 of the package substrate 10, and the fourth connector 143 may be formed close to the second side S2 of the package substrate 10. All of the second chip pad 121 of the second semiconductor chip 120, the third chip pad 131 of the third semiconductor chip 130, and the third chip pad 131 of the fourth semiconductor chip 140 may be exposed so that the second connector 123, the third connector 133, and the fourth connector 143 may be continuously formed in the second connecting process. A semiconductor chip stack 100 including the first semiconductor die 119, the second semiconductor die 129, the third semiconductor die 139, and the fourth semiconductor die 149 may be mounted and stacked on the package substrate 10.

Thereafter, referring to FIG. 1A, the method may further include performing a molding process to form a molding member 90 covering the semiconductor chip stack 100, and performing a solder ball mounting process to form external connectors 19.

The method of manufacturing the semiconductor package according to the embodiment of the present disclosure may include continuously performing the first chip stack process, the first connecting process, the second chip stack process, and the second connecting process. The first chip stack process may include stacking the lowermost first semiconductor die 119 on the package substrate 10. The first connecting process may include forming the first connector 113 electrically connecting the first chip pad 111 of the first semiconductor chip 110 of the first semiconductor die 119 to the first substrate pad 11 of the package substrate 10. The second chip stack process may include continuously stacking the second to fourth semiconductor dies 129, 139, and 149 on the first semiconductor die 119. The second connecting process may include electrically connecting the second to fourth chip pads 121, 131, and 141 of the second to fourth semiconductor dies 129, 139, and 140 to the second to fourth substrate pads 12, 13, and 14 of the package substrate 10, respectively. In the first chip stack process, the first semiconductor die 119 may be adhered and stacked using the first adhesive layer 115 having the first thickness t1. In the second chip stack process, the second to fourth semiconductor dies 129, 139, and 149 may be adhered and stacked using the second to fourth adhesive layers 125, 135, and 145 having the second thickness t2, respectively. That is, referring to FIGS. 1A to 1C, the first thickness t1 may be thicker than the second thickness t2. The first to fourth semiconductor chips 110, 120, 130, and 140 may have substantially the same thickness Tc. In an embodiment, because the stack processes are performed very precisely, if the thicknesses of the semiconductor dies 119, 129, 139, and 149, that is, the adhesive layers 115, 125, 135, and 145, are not the same, the semiconductor dies 119, 129, 139, and 149 cannot be stacked by performing the same stack process. In an embodiment, if the thicknesses of the adhesive layers 115, 125, 135, and 145 are different from each other, the semiconductor dies 119, 129, 139, and 149 cannot be stably stacked because the pressure, temperature, process time, and other process conditions performed for the chip stack are not the same. In an embodiment the present disclosure, the second to fourth adhesive layers 125, 135, and 145 of the second to fourth semiconductor dies 129, 139, and 149 stacked in the second chip stack processes have substantially the same thickness t2. Therefore, according to various embodiments described in the present disclosure, the semiconductor dies 119, 129, 139, and 149 having different thicknesses T1 and T2 may be stably stacked.

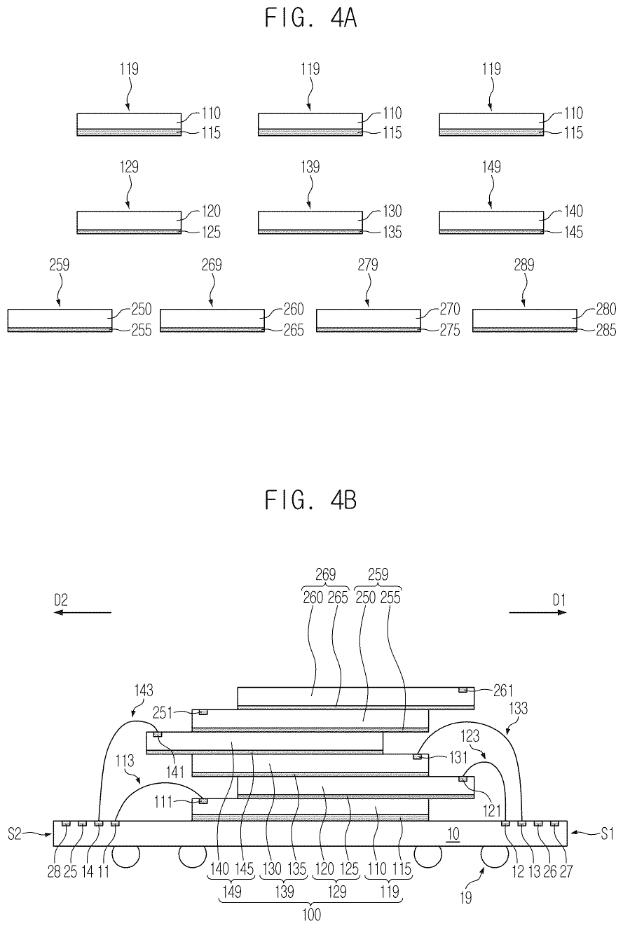

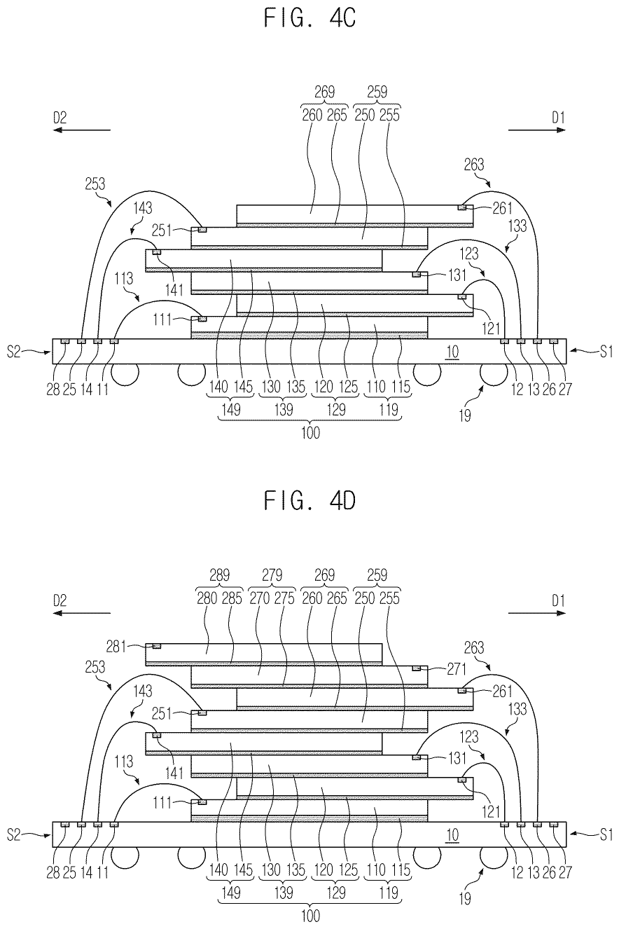

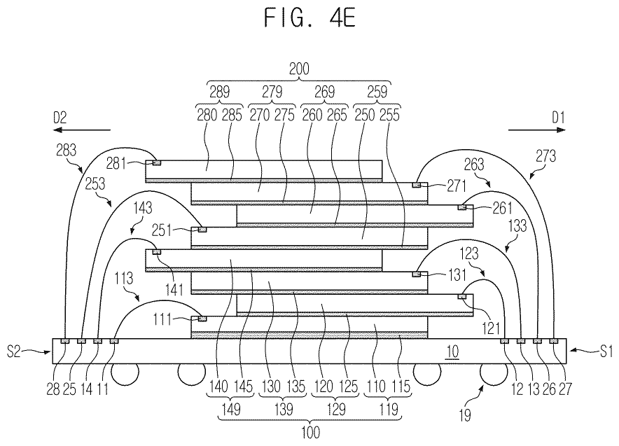

FIGS. 4A to 4E are views illustrating a method of manufacturing a semiconductor package according to an embodiment of the present disclosure.

Referring to FIG. 4A, the method of manufacturing the semiconductor package may include performing the processes described with reference to FIG. 3A, separating the first wafer W1 and the first adhesive film L1 to make a plurality of first semiconductor dies 119, and separating the second wafer W2 and the second adhesive films L2 to make a plurality of second to eighth semiconductor dies 129, 139, 259, 269, 279, and 289, respectively. The fifth semiconductor die 259 may include a fifth semiconductor chip 250 and a fifth adhesive layer 255 on a lower surface (backside surface) of the fifth semiconductor chip 250. The sixth semiconductor die 269 may include a sixth semiconductor chip 260 and a sixth adhesive layer 265 on a lower surface (backside surface) of the sixth semiconductor chip 260. The seventh semiconductor die 279 may include a seventh semiconductor chip 270 and a seventh adhesive layer 275 on a lower surface (backside surface) of the seventh semiconductor chip 270. The eighth semiconductor die 289 may include an eighth semiconductor chip 280 and an eighth adhesive layer 285 on a lower surface (backside surface) of the eighth semiconductor chip 280.

Referring to FIG. 4B, the method may further include continuously stacking a fifth semiconductor die 259 and a sixth semiconductor die 269 on the fourth semiconductor die 149 of the first semiconductor chip stack 100 by performing the processes described with reference to FIGS. 3C to 3F. The fifth semiconductor die 259 may be offset-stacked from the fourth semiconductor chip 140 in the first direction D1 of the package substrate 10 so that a portion of an upper surface on which the fourth chip pad 141 disposed is exposed. The fifth semiconductor chip 250 may include a fifth chip pad 251 disposed on an upper surface close to the second side S2 of the package substrate 10. The sixth semiconductor die 269 may be offset-stacked from the fifth semiconductor chip 250 in the first direction D1 so that a portion of an upper surface on which the fifth chip pad 251 disposed is exposed. The sixth semiconductor chip 260 may include a sixth chip pad 261 disposed on an upper surface close to the first side S1 of the package substrate 10.

Referring to FIG. 4C, the method may further include performing a third connecting process to electrically connect the fifth chip pad 251 of the fifth semiconductor chip 250 to the fifth substrate pad 25 of the package substrate 10 using a fifth connector 253, and to electrically connect the sixth chip pad 261 of the sixth semiconductor chip 260 to the sixth substrate pad 26 of the package substrate 10 using a sixth connector 263. Each of the fifth connector 253 and the sixth connector 263 may include a bonding wire. The third connecting process may include a third wire bonding process. The third connecting process may include continuously forming the fifth connector 253 and the sixth connector 263. The fifth connector 253 may be formed close to the second side S2 of the package substrate 10, and the sixth connector 263 may be formed close to the first side S1 of the package substrate 10.

Referring to FIG. 4D, the method may further include performing a fourth chip stack process to stack a seventh semiconductor die 279 and an eighth semiconductor die 289 on the sixth semiconductor die 269, continuously. The seventh semiconductor die 279 may be offset-stacked from the sixth semiconductor chip 260 in the second direction D2 so that a portion of the upper surface on which the sixth chip pad 261 of the sixth semiconductor chip 260 disposed is exposed. The seventh semiconductor chip 270 may include a seventh chip pad 271 disposed on an upper surface close to the first side S1 of the package substrate 10. The eighth semiconductor die 289 may be offset-stacked from the seventh semiconductor chip 270 in the second direction D2 so that a portion of the upper surface on which the seventh chip pad 271 of the seventh semiconductor chip 270 disposed is exposed. The eighth semiconductor chip 280 may include an eighth chip pad 281 disposed on an upper surface close to the third side S2 of the package substrate 10.

Referring to FIG. 4E, the method may further include performing a fourth connecting process to electrically connect the seventh chip pad 271 of the seventh semiconductor chip 270 of the seventh semiconductor die 279 to the seventh substrate pad 27 of the package substrate 10 using a seventh connector 273, and to electrically connect the eighth chip pad 281 of the eighth semiconductor chip 280 of the eighth semiconductor die 289 to the eighth substrate pad 28 of the package substrate 10 using an eighth connector 283. Each of the seventh connector 273 and the eighth connector 283 may include a bonding wire. The fourth connecting process may include a fourth wire bonding process. The fourth connecting process may include continuously forming the seventh connector 273 and the eighth connector 283. The seventh connector 273 may be disposed close to the first side S1 of the package substrate 10, and the eighth connector 283 may be disposed close to the second side S2 of the package substrate 10. The additional semiconductor chip stack 200 including the fifth semiconductor die 259, the sixth semiconductor die 269, the seventh semiconductor die 279, and the eighth semiconductor die 289 may be mounted and stacked on the semiconductor chip stack 100.

Thereafter, referring to FIG. 2, the method may further include performing a molding process to form a molding member 90 covering the semiconductor chip stacks 100 and 200, and performing a solder ball mounting process to form external connectors 19.

According to embodiments of the present disclosure, even if foreign substances are present on the package substrate, it may be covered with an adhesive layer having a sufficient thickness. According to embodiments of the present disclosure, by forming only a thick adhesive layer of the semiconductor die stacked in the lowermost layer, the total height of the stacked semiconductor dies and the space between the semiconductor dies can be kept to a minimum.

According to embodiments of the present disclosure, by successively stacking three semiconductor dies in one stack process, it can be prevented the number of chip stack processes is increased.

While the present disclosure has been described with respect to the specific embodiments, it will be apparent to those skilled in the art that various changes and modifications may be made without departing from the spirit and scope of the disclosure as defined in the following claims.

1. A method of manufacturing a semiconductor package comprising:
mounting a first semiconductor die over a package substrate,
forming a first connector to electrically connect the first semiconductor die to the package substrate,
offset-stacking a second semiconductor die over the first semiconductor die in a first direction,
offset-stacking a third semiconductor die on the second semiconductor die in a second direction,
offset-stacking a fourth semiconductor die on the third semiconductor die in the second direction,
forming a second connector to electrically connect the second semiconductor die to the package substrate,
forming a third connector to electrically connect the third semiconductor die to the package substrate, and
forming a fourth connector to electrically connect the fourth semiconductor die to the package substrate.

2. The method of claim 1,
wherein the package substrate includes;
a first side and a second side; and
first to fourth substrate pads,
wherein:
the first substrate pad and the fourth substrate pad are disposed closer to the first side than the second side,
the second substrate pad and the third substrate pad are disposed closer to the second side than the first side, and
the first to fourth substrate pads are electrically connected to the first to fourth semiconductor dies through the first to fourth connectors, respectively.

3. The method of claim 2, wherein:
the first semiconductor die includes a first semiconductor chip and a first adhesive layer over a lower surface of the first semiconductor chip,
the second semiconductor die includes a second semiconductor chip and a second adhesive layer over a lower surface of the second semiconductor chip,
the third semiconductor die includes a third semiconductor chip and a third adhesive layer over a lower surface of the third semiconductor chip, and
the fourth semiconductor die includes a fourth semiconductor chip and a fourth adhesive layer over a lower surface of the fourth semiconductor chip,
the first adhesive layer has a first thickness,
each of the second to fourth adhesive layers has a second thickness,
the first thickness is thicker than the second thickness.

4. The method of claim 3,
wherein the first semiconductor die includes a first chip pad disposed over an upper surface of the first semiconductor chip to be closer to the second side than the first side,
wherein the second semiconductor die includes a second chip pad disposed over an upper surface of the second semiconductor chip to be closer to the first side than the second side,
wherein the third semiconductor die includes a third chip pad disposed over an upper surface of the third semiconductor chip to be closer to the first side than the second side,
wherein the fourth semiconductor die includes a fourth chip pad disposed over the upper surface of the fourth semiconductor chip to be closer to the second side than the first side, and
wherein the first to fourth chip pads are electrically connected to the first to fourth substrate pads through the first to fourth connectors, respectively.

5. The method of claim 3,
wherein the first thickness is equal to or greater than 20 micrometer (μm), and the second thickness is equal to or less than 10 μm.

6. The method of claim 3,
wherein a vertical thickness of each of the first to fourth semiconductor chips is equal to or less than 60 μm.

7. The method of claim 1,
offset-stacking a fifth semiconductor die over the fourth semiconductor die in the first direction,
offset-stacking a sixth semiconductor die over the fifth semiconductor die in the first direction,
forming a fifth connector electrically connecting the fifth semiconductor die to the package substrate,
forming a sixth connector electrically connecting the sixth semiconductor die to the package substrate,
offset-stacking a seventh semiconductor die over the sixth semiconductor die in the second direction,
offset-stacking an eighth semiconductor die over the seventh semiconductor die in the second direction,
forming a seventh connector electrically connecting the seventh semiconductor die to the package substrate, and
forming an eighth connector electrically connecting the eighth semiconductor die to the package substrate.

8. The method of claim 7, wherein:
the fifth semiconductor die includes a fifth semiconductor chip and a fifth adhesive layer disposed over a lower surface of the fifth semiconductor chip,
the sixth semiconductor die includes a sixth semiconductor chip and a sixth adhesive layer disposed over a lower surface of the sixth semiconductor chip,
the seventh semiconductor die includes a seventh semiconductor chip and a seventh adhesive layer disposed over a lower surface of the seventh semiconductor chip,
the eighth semiconductor die includes an eighth semiconductor chip and an eighth adhesive layer disposed over a lower surface of the eighth semiconductor chip,
wherein each of the fifth to eighth adhesive layers has the second thickness.

9. A method of manufacturing a semiconductor package comprising:
forming a first adhesive film having a first thickness over a backside surface of a first wafer, forming a second adhesive film having a second thickness over a backside surface of a second wafer,
dicing the first wafer and the first adhesive film to form a first semiconductor die having a first semiconductor chip and a first adhesive layer,
dicing the second wafer and the second adhesive film to form second to fourth semiconductor dies having second to fourth semiconductor chips and second to fourth adhesive layers, respectively,
mounting the first semiconductor die on a package substrate, and
stacking sequentially the second to fourth semiconductor dies over the first semiconductor die,
wherein:
the first adhesive film has a first thickness,
the second adhesive film has a second thickness, and
the first thickness is thicker than the second thickness.

10. The method of claim 9, wherein:
the second semiconductor die is offset-stacked on the first semiconductor die in a first direction,
the third semiconductor die is offset-stacked on the second semiconductor die in a second direction,
the fourth semiconductor die is offset-stacked on the third semiconductor die in the second direction, and
the first direction and the second direction are opposite to each other.

11. The method of claim 9,
wherein the package substrate includes:
a first side and a second side; and
first to fourth substrate pads,
wherein:
the first and fourth substrate pads are disposed closer to the first side than the second side,
the second and third substrate pads are disposed closer to the second side than the first side, and
the first to fourth substrate pads are electrically connected to the first to fourth semiconductor dies using first to fourth connectors, respectively.

12. The method of claim 11, wherein:
the first semiconductor die includes a first semiconductor chip and a first adhesive layer over a lower surface of the first semiconductor chip,
the second semiconductor die includes a second semiconductor chip and a second adhesive layer over a lower surface of the second semiconductor chip,
the third semiconductor die includes a third semiconductor chip and a third adhesive layer over a lower surface of the third semiconductor chip,
the fourth semiconductor die includes a fourth semiconductor chip and a fourth adhesive layer over a lower surface of the fourth semiconductor chip,
the first adhesive layer has the first thickness, and each of the second to fourth adhesive layers has the second thickness.

13. The method of claim 12, wherein:
the first semiconductor die includes a first chip pad disposed over an upper surface of the first semiconductor chip to be closer to the second side than the first side,
the second semiconductor die includes a second chip pad disposed over an upper surface of the second semiconductor chip to be closer to the first side than the second side,
the third semiconductor die includes a third chip pad disposed over an upper surface of the third semiconductor chip to be closer to the first side than the second side,
the fourth semiconductor die includes a fourth chip pad disposed over an upper surface of the fourth semiconductor chip to be closer to the second side than the first side, and
the first to fourth chip pads are electrically connected to the first to fourth substrate pads through the first to fourth connectors, respectively.

14. The method of claim 13, further comprising:
offset-stacking a fifth semiconductor die over the fourth semiconductor die in the first direction,
offset-stacking a sixth semiconductor die over the fifth semiconductor die in the first direction,
forming a fifth connector electrically connecting the fifth semiconductor die to the package substrate,
forming a sixth connector electrically connecting the sixth semiconductor die to the package substrate,
offset-stacking a seventh semiconductor die over the sixth semiconductor die in the second direction,
offset-stacking an eighth semiconductor die over the seventh semiconductor die in the second direction,
forming a seventh connector electrically connecting the seventh semiconductor die to the package substrate, and
forming an eighth connector electrically connecting the eighth semiconductor die to the package substrate.

15. The method of claim 14,
wherein the fifth to eighth semiconductor dies include, respectively:
fifth to eighth semiconductor chips; and
fifth to eighth adhesive layers disposed over lower surfaces of the fifth to eighth semiconductor chips, respectively,
wherein each of the fifth to eighth adhesive layers has the second thickness.

16. The method of claim 13,
wherein the first thickness is equal to or greater than 20 micrometer (μm), and the second thickness is equal to or less than 10 μm.

17. The method of claim 13,
wherein a vertical thickness of each of the first to fourth semiconductor chips is equal to or less than 60 μm.
